(19) United States
(12) Patent Application Publication
(10) Pub. No.: US 2012/0161180 A1
(43) Pub. Date: Jun. 28, 2012

(54) LED PACKAGE

(75) Inventors: Tetsuro Komatsu, Fukuoka-ken (JP); Hiroaki Oshio, Fukuoka-ken (JP)

(73) Assignee: KABUSHIKI KAISHA TOSHIBA, Tokyo (JP)

(21) Appl. No.: 13/234,509

(22) Filed: Sep. 16, 2011

(30) Foreign Application Priority Data
Dec. 28, 2010 (JP) 2010-293948

(51) Int. Cl. H01L 33/50; H01L 33/60

(52) U.S. Cl. 257/98; 257/E33.061; 257/E33.072

(57) ABSTRACT

According to one embodiment, an LED package includes a first lead frame and a second lead frame, an LED chip and a resin body. The resin body covers the LED chip and the top face, a part of the bottom face and a part of the end face, of each of the first and the second lead frames, and exposes the remaining part of the bottom face and the remaining part of the end face. The resin body includes a first part and a second part. The first part is disposed between the top face of the LED chip and a region immediately above the LED chip of the top face of the resin body and transmits light emitted by the LED chip. The second part surrounds the first part and has a transmittance of the light lower than a transmittance in the first part.

### CROSS-REFERENCE TO RELATED APPLICATIONS

This application is based upon and claims the benefit of priority from the prior Japanese Patent Application No. 2010-293948, filed on Dec. 28, 2010; the entire contents of which are incorporated herein by reference.

### FIELD

Embodiments described herein relate generally to an LED (Light Emitting Diode) package.

### BACKGROUND

In a conventional LED package having an LED chip light mounted thereon, a bowl-shaped envelope made of white resin is provided, and the LED chip is mounted on the bottom of the envelope and then embedded by encapsulating transparent resin into the envelope for the purpose of controlling the light distribution characteristics to raise light extraction efficiency from the LED package. Usually, the envelope has been made of polyamide thermoplastic resin. Recently, however, further cost reduction has been required due to expanded application range of LED packages.

### BRIEF DESCRIPTION OF THE DRAWINGS

FIG. 1 is perspective view showing an LED package according to a first embodiment;

FIGS. 2A to 2D show the LED package according to the first embodiment;

FIGS. 3A to 3C show lead frames of the LED package according to the first embodiment;

FIG. 4 is a flow chart showing a method of manufacturing the LED package according to the first embodiment;

FIGS. 5A to 5H are process cross-sectional views showing a method of forming a lead frame sheet of the first embodiment;

FIG. 6A is a plan view showing the lead frame sheet of the first embodiment, whereas FIG. 6B is a partially enlarged plan view showing an element region of the lead frame sheet;

FIGS. 7A to 7D, FIGS. 8A to 8C, FIGS. 9A and 9B are process cross-sectional views showing a method of manufacturing the LED package according to the first embodiment;

FIG. 10 is perspective view showing an LED package according to a second embodiment;

FIGS. 11A to 11D show the LED package according to the second embodiment;

FIG. 12 is perspective view showing an LED package according to a third embodiment;

FIGS. 13A to 13D show the LED package according to the third embodiment;

FIG. 14 is perspective view showing an LED package according to a fourth embodiment;

FIGS. 15A to 15D show the LED package according to the fourth embodiment;

FIG. 16 is perspective view showing an LED package according to a fifth embodiment;

FIGS. 17A to 17D show the LED package according to the fifth embodiment;

FIG. 18 is perspective view showing an LED package according to a sixth embodiment;

FIGS. 19A to 19D show the LED package according to the sixth embodiment; and

FIGS. 20A to 20C show lead frames of the LED package according to the sixth embodiment.

### DETAILED DESCRIPTION

In general, according to one embodiment, an LED package includes a first lead frame and a second lead frame spaced apart from each other, an LED chip and a resin body. The LED chip is provided above the first lead frame and the second lead frame and has one terminal connected to the first lead frame and the other terminal connected to the second lead frame. The resin body covers the LED chip. The resin body covers the top face, a part of the bottom face and a part of the end face, of each of the first and the second lead frames. The resin body exposes the remaining part of the bottom face and the remaining part of the end face. The resin body includes a first part and a second part. The first part is disposed between the top face of the LED chip and a region immediately above the LED chip of the top face of the resin body. The first part transmits light emitted by the LED chip. The second part surrounds the first part. The second part has a transmittance of the light lower than a transmittance in the first part. And, an external shape of the resin body defines an external shape of the LED package.

Embodiments of the invention will now be described with reference to the drawings.

To begin with, a first embodiment will be described.

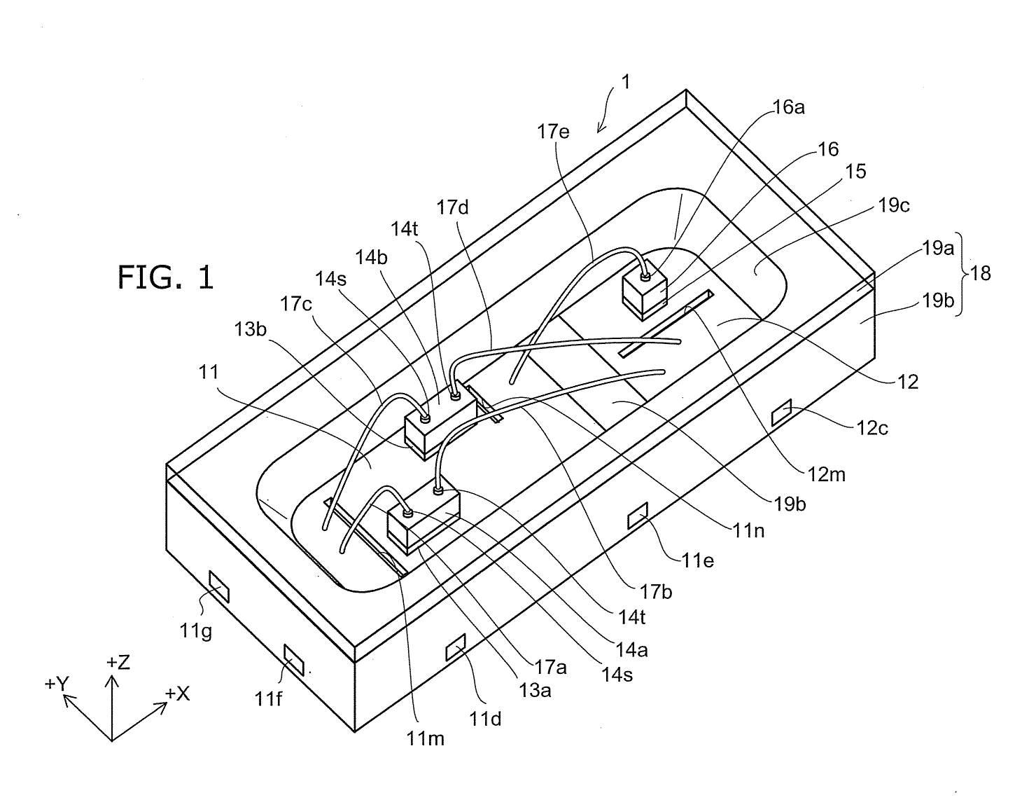

FIG. 1 is perspective view showing an LED package according to the embodiment;

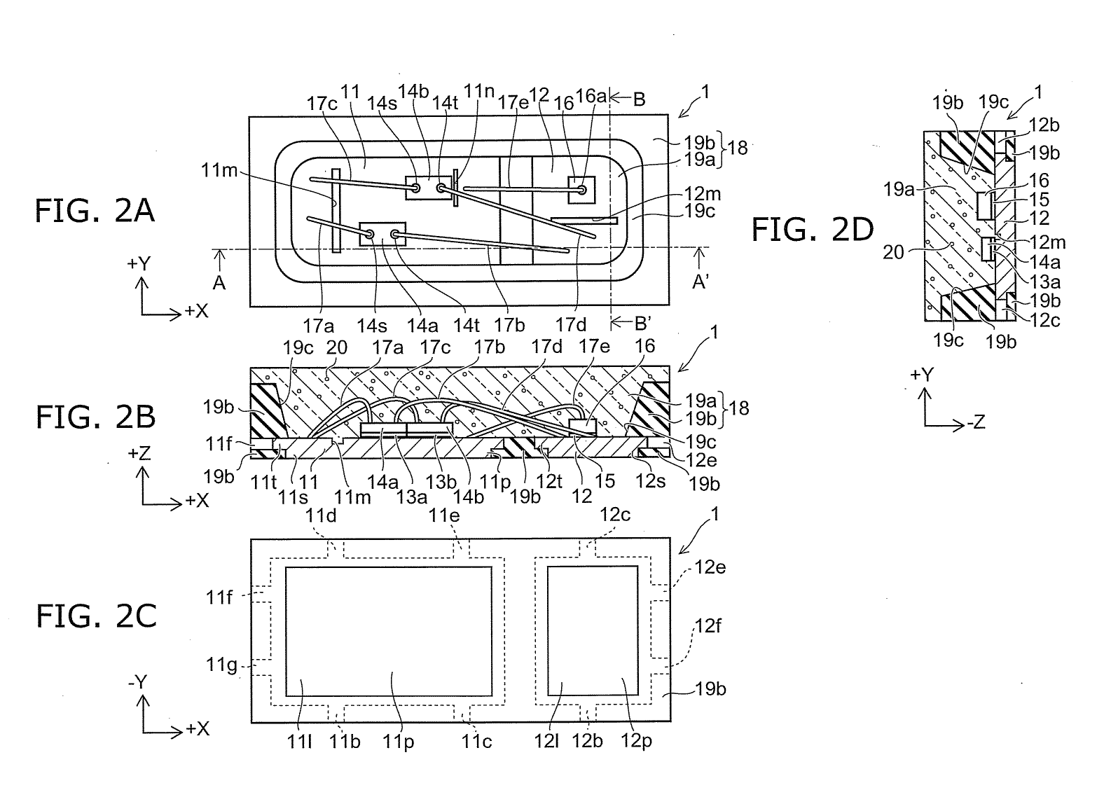

FIGS. 2A to 2D show the LED package according to the embodiment, in which FIG. 2A is a top view, FIG. 2B is a cross-sectional view taken along line A-A′ shown in FIG. 2A, FIG. 2C is a bottom view, and FIG. 2D is a cross-sectional view taken along line B-B′ shown in FIG. 2A; and

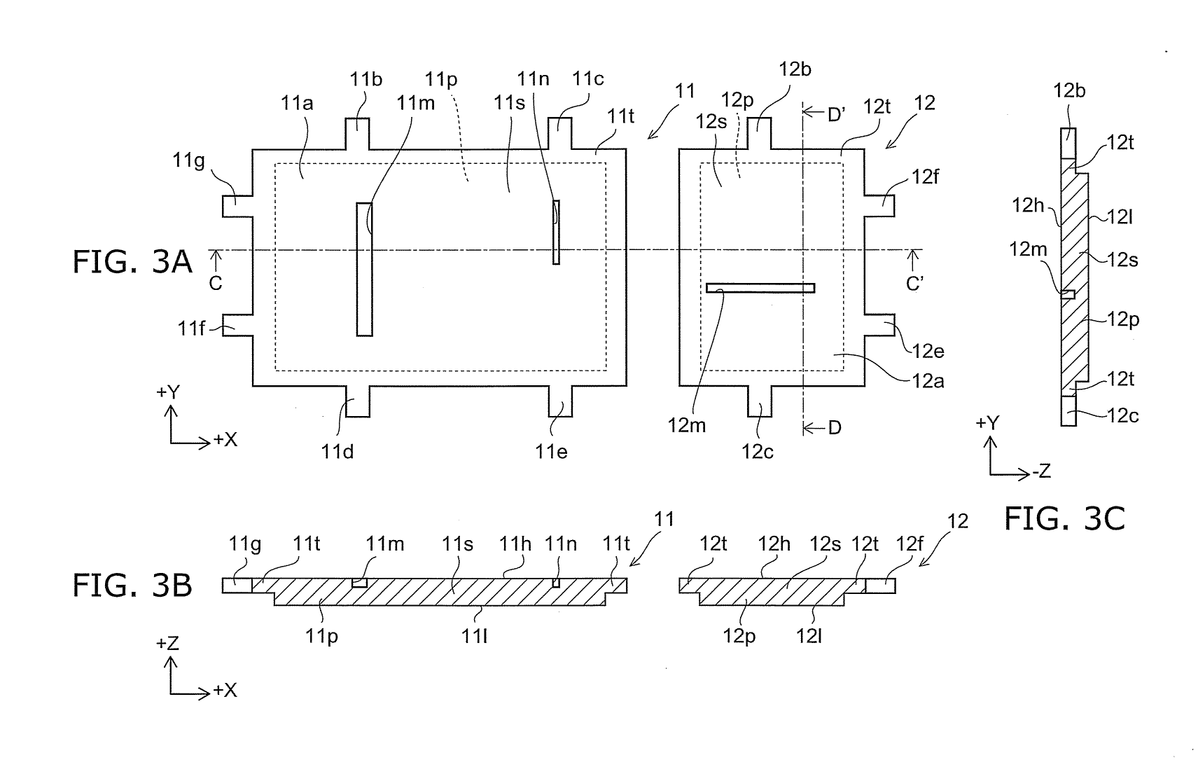

FIGS. 3A to 3C show lead frames of the LED package according to the embodiment, in which FIG. 3A is a top view, FIG. 3B is a cross-sectional view taken along line C-C′ shown in FIG. 3A, and FIG. 3C is a cross-sectional view taken along line D-D′ shown in FIG. 3A.

As shown in FIGS. 1 to 3, a pair of lead frames 11 and 12 is provided in an LED package 1 according to the embodiment. The lead frames 11 and 12 are planar, arranged on the same plane, and spaced apart from each other. The lead frames 11 and 12 are made of an identical conductive material and include a silver plating layer formed on the top and bottom faces of a copper sheet, for example. No silver plating layer is formed on end faces of the lead frames 11 and 12, with the copper sheet being exposed therefrom.

In the following, the XYZ orthogonal coordinate system is introduced for convenience of explanation in the specification. A direction from the lead frame 11 toward the lead frame 12, among the directions parallel with the top faces of the lead frames 11 and 12, is defined as “+X direction”; a direction upward, i.e., toward where an LED chip described below is mounted, seen from the lead frames, among the directions perpendicular to the top faces of the lead frames 11 and 12, is defined as “+Z direction”; and one of the directions orthogonal to both the +X and +Z directions is defined as “+Y direction”. Directions opposite to the +X, +Y, and +Z directions are respectively defined as the −X, −Y, and −Z directions. In addition, the “+X direction” and the “−X direction”, for example, may also be collectively referred to as “X direction”.

The lead frame 11 has provided thereon a base portion 11a which is rectangular seen from the Z direction, with six extending portions 11b, 11c, 11d, 11e, 11f, and 11g extending from the base portion 11a. The extending portions 11b and 11c extend toward the +Y direction from a part at the −X direction side and a part at the +X direction side on the end edge facing the +Y direction of the base portion 11a. The extending portions 11d and 11e extend toward the −Y direction from a part at the −X direction side and a part at the +X direction side on the end edge facing the −Y direction of the base portion 11a. The positions of the extending portions 11b and 11d along the X direction are identical to each other, and the positions of the extending portions 11c and 11e are identical to each other. The extending portions 11f and 11g extend toward the −X direction from a part located further in the −Y direction and a part located further in the +Y direction on the end edge facing the −X direction of the base portion 11a. As thus described, the extending portions 11b to 11g respectively extend from three different sides f the base portion 11.

The lead frame 12 has a shorter length along the X direction than the lead frame 11 and the same length along the Y direction. The lead frame 12 has a base portion 12a provided thereon which is rectangular seen from the Z direction, with four extending portions 12b, 12c, 12d, and 12e extending out from the base portion 12a. The extending portion 12b extends toward the +Y direction from the vicinity of the central part along the X direction of the end edge facing the +Y direction of the base portion 12a. The extending portion 12c extends toward the −Y direction from the vicinity of the central part along the X direction of the end edge facing the −Y direction of the base portion 12a. The extending portions 12d and 12e extend toward the +X direction from a part t the side of the −Y direction and a part located further in the +Y direction on the end edge facing the +X direction of the base portion 12a. As thus described the extending portions 12b to 12e respectively extend from different three sides of the base portion 12a. The width of the extending portions 11g and 11f of the lead frame 11 may be either identical to or different from the width of the extending portions 12d and 12e of the lead frame 12. However, it becomes easier to distinguish an anode from a cathode if the width of the extending portions 11d and 11e are made different from the width of the extending portions 12d and 12e.

A protrusion 11p is formed on the central part of the base portion 11a at a bottom face 11l of the lead frame 11. Accordingly, the thickness of the lead frame 11 has a two-level value, with the central part of the base portion 11a, i.e., the part on which a protrusion 11p is formed, being a relatively thick thick-plate portion 11s, and the circumference and the extending portions 11b to 11g of the base portion 11a being a relatively thin thin-plate portion 11t. Similarly, the central part of the base portion 12a of the bottom face 12l of the lead frame 12 has a protrusion 12p formed thereon. Accordingly, the thickness 2 of the lead frame 12 also has a two-level value, with the central part of the base portion 12a being a relatively thick thick-plate portion 12s since it has the protrusion 12p formed thereon, and the circumference and the extending portions 12b to 12e of the base portion 12a being a relatively thin thin-plate portion 12t. In other words, a notch is formed on the bottom face of the circumference of the base portions 11a and 12a.

As thus described, the protrusions 11p and 12p are formed in a region spaced apart from mutually facing end edges of the lead frames 11 and 12, and the region including these end edges is the thin-plate portions 11t and 12t. The top face 11h of the lead frame 11 and the top face 12h of the lead frame 12 are coplanar, and the bottom face the protrusion 11p of the lead frame 11 and the bottom face of the protrusion 12p of the lead frame 12 are coplanar. In addition, the position of the top face of the extending portions along the Z direction coincides with the position of the top face of the lead frames 11 and 12. Therefore, the extending portions are arranged on the same XY plane.

The region located further in the −X direction on the top face 11h of the lead frame 11 has formed thereon a groove 11m extending toward the Y direction. In addition, the region located further in the +X+Y direction on the top face 11h has formed thereon a groove 11n extending toward the Y direction. Furthermore, the central part along the Y direction on the top face 12h of the lead frame 12 has formed thereon a groove 12m extending toward the X direction. The grooves 11m, 11n, and 12m are all formed inside a region immediately above the thick-plate portions 11s or 12s, i.e., the protrusions 11p or 12p so that they neither reach the circumference of the thick-plate portion nor penetrate through the lead frame along the Z direction.

Two regions, within the top face 11h of the lead frame 11, which are the thick-plate portion 11s and located between the groove 11m and the groove 11n have die mount materials 13a and 13b (collectively referred to as “dye mount material 13” in the following) adhered thereon. In the embodiment, the die mount materials 13a and 13b may be either conductive or insulative. If the die mount material 13 is conductive, the die mount material 13 is formed by silver paste, solder, or eutectic solder, for example. If the die mount material 13 is insulative, the die mount material 13 is formed by transparent resin paste, for example.

The die mount materials 13a and 13b respectively have LED chips 14a and 14b (collectively referred to as “LED chip 14” in the following) provided thereon. In other words, the die mount material 13 has LED chip 14 fixed on the lead frame 11, and thereby the LED chip 14 is mounted on the lead frame 11. The LED chip 14b is provides at the side along the +X direction and the side along the +Y direction, seen from the LED chip 14a. In other words, the LED chips 14a and 14b are located diagonally to each other. The LED chip 14 includes semiconductor layers of gallium nitride (GaN) stacked on a sapphire substrate, for example, with a rectangular solid shape, having terminals 14s and 14t provided on the top face thereof. The LED chip 14 emits blue light, for example, by having a voltage supplied between the terminals 14s and 14t.

In addition, a die mount material 15 is adhered to a region, within the top face 12h of the lead frame 12, which is the thick-plate portion 12s and located further in the +Y direction than the groove 12m. The die mount material 15 is formed by a conductive material such as silver paste, solder, or eutectic solder, for example. The die mount material 15 has a Zener diode chip (ZD tip) 16 provided thereon. In other words, the die mount material 15 fixes the ZD chip 16 on the lead frame 12, and thereby the ZD chip 16 is mounted on the lead frame 12. The ZD chip 16 is a vertically conductive chip, having its bottom face terminal (not shown) connected to the lead frame 12 via the die mount material 15.

The terminals 14s and 14t of the LED chips 14a and 14b, and the top face terminal 16a of ZD chip 16 are connected to the lead frames 11 or 12 by wires 17a to 17e (collectively referred to as “wire 17” in the following). The wire 17 is formed by metal such as gold or aluminum, for example. The connection state between the terminals and the lead frames will be specifically described below. Note that the wire 17 is not shown in FIG. 3D. The same goes for the similar drawings described below.

One end of the wire 17a is bonded to the terminal 14s of the LED chip 14a. The wire 17a is drawn from the terminal 14s of the LED chip 14a toward the +Z direction (immediately upward) and bent toward a direction between the −X and −Z directions, whereas the other end of the wire 17a is bonded to a region located further in the −X direction than the groove 11m on the top face 11h of the lead frame 11. Accordingly, the terminal 14s of the LED chip 14a is connected to the lead frame 11 via the wire 17a.

One end of the wire 17b is bonded to the terminal 14t of the LED chip 14a. The wire 17b is drawn from the terminal 14t of the LED chip 14a toward the +Z direction and bent toward a direction between the +X and −Z directions, whereas the other end of the wire 17b is bonded to a region located further in the −Y direction than the groove 12m on the top face 12h of the lead frame 12. Accordingly, the terminal 14t of the LED chip 14a is connected to the lead frame 12 via the wire 17b.

One end of the wire 17c is bonded to the terminal 14s of the LED chip 14b. The wire 17c is drawn from the terminal 14s of the LED chip 14b toward the +Z direction and bent toward a direction between the −X and −Z directions, whereas the other end of wire 17c is bonded to a region located further in the −X direction than the groove 11m on the top face 11h of the lead frame 11. Accordingly, the terminal 14s of the LED chip 14b is connected to the lead frame 11 via the wire 17c.

One end of the wire 17d is bonded to the terminal 14t of the LED chip 14b. The wire 17d is drawn from the terminal 14t of the LED chip 14b toward the +Z direction and bent toward a direction among the +X, −Y, and −Z directions, whereas the other end of wire 17d is bonded to a region located further in the −Y direction than the groove 12m on the top face 12h of the lead frame 12. Accordingly, the terminal 14t of the LED chip 14b is connected to the lead frame 12 via the wire 17d.

One end of the wire 17e is bonded to the top face terminal 16a of the ZD chip 16. The wire 17e is drawn from the top face terminal 16a toward the +Z direction and bent toward a direction between the −X and −Z directions, whereas the other end of the wire 17e is bonded to a region located further in the +X direction than the groove 11n on the top face 11h of the lead frame 11. Accordingly, the top face terminal 16a of ZD chip 16 is connected to the lead frame 11 via the wire 17e.

As thus described, the LED chips 14a and 14b, and the ZD chip 16 are connected between the lead frames 11 and 12 in parallel with each other. Additionally, on the top face 11h of the lead frame 11, the region where the wires 17a and 17c are bonded and the region where the die mount materials 13a and 13b are adhered are partitioned by the groove 11m. In addition, region where the wire 17e is bonded and the region where the die mount material 13b is adhered is partitioned by the groove 11n. Furthermore, on the top face 12h of the lead frame 12, the region where the wire 17b and 17d are bonded and the region where the die mount material 15 is adhered are partitioned by the groove 12m.

In addition, the LED package 1 has a resin body 18 provided thereon. The resin body 18 has a rectangular solid external shape, with the lead frames 11 and 12, the die mount material 13, the LED chip 14, the die mount material 15, the ZD chip 16 and the wire 17 embedded therein, so that the external shape of the resin body 18 is the external shape of the LED package 1. A part of the lead frame 11 and a part of the lead frame 12 are exposed on the bottom and side faces of the resin body 18. In other words, the resin body 18 covers the LED chip 14, the entire top face of each of the lead frames 11 and 12, and a part of the bottom face and a part of the end face, exposing the remaining part of the bottom face and remaining part of the end face. In the specification, “to cover” is meant to include both cases where the object which provides covering is and is not in contact with the object to be covered.

More specifically, in the bottom face 111 of the lead frame 11, the bottom face of the protrusion 11p is exposed on the bottom face of the resin body 18 and the tip faces of the extending portions 11b to 11g are exposed on the side of the resin body 18. On the other hand, the entire top face 11h of the lead frame 11, a region other than the protrusion 11p of the bottom face 11f, i.e., the bottom face of each extending portion and the thin-plate portion 11t, and a region other than the tip face of the extending portion of the side face, i.e., the side face of the protrusion 11p, and the end face of the base portion 11a and the side face of the extending portion are covered by the resin body 18. Similarly, the bottom face of the protrusion 12p of the lead frame 12 is exposed on the bottom face of the resin body 18, and the tip faces of the extending portions 12b to 12e are exposed on the side face of the resin body 18. On the other hand, the entire top face 12h of the lead frame 12, a region other than the protrusion 12p of the bottom face 12l, i.e., the bottom face of each extending portion and the thin-plate portion 12t, and a region other than the tip face of the extending portion, i.e., the side face of the protrusion 12p, the end face of the base portion 12a, and the side face of the extending portion are covered by the resin body 18. In the LED package 1, the bottom faces of the protrusions 11p and 12p exposed on the bottom face of the resin body 18 become an external electrode pad. As thus described, the resin body 18 has a rectangular shape, seen from above, and the tip faces of the extending portions provided on each lead frame are exposed on three mutually different sides of the resin body 18.

The resin body 18 has a transparent part 19a and a white part 19b provided therein. The transparent part 19a is a part through which light emitted by the LED chip 14 and light emitted by a phosphors 20 described below (collectively referred to as “emitted light” in the following) transmit, and is formed by transparent silicone resin which, for example. Here “transparent” also includes being translucent. The white part 19b is a part where the transmittance of the emitted light is lower than the transmittance of the emitted light in the transparent part 19a, and is formed by white silicone resin, for example. In addition, the reflectance of the emitted light on the external surface of the white part 19b is higher than the reflectance of the emitted light on the external surface of the transparent part 19a. As a specific example, the transparent part 19a is formed by dimethyl silicone resin. Although the white part 19b is also formed by dimethyl silicone resin, it contains a reflective material. The reflective material has titanium oxide, for example, as its primary constituent.

Accordingly, a reflectance not less than 80% and not less than 90%, for example, can be realized in the visible light region and a region close to the visible light region in the ultraviolet region, for example, a region where the wavelength is in a range of 800 to 350 nm.

The lowermost layer part of the resin body 18, i.e., a virtual plane including the top face 11h of the lead frame 11 and the top face 12h of the lead frame 12, and a part located below them are the white part 19b. Therefore, the bottom face of the resin body 18 includes the white part 19b. On the other hand, the uppermost layer part in the resin body 108, i.e., the part which wire 17 does not reach is the transparent part 19a. Accordingly, the top face of the resin body 18 includes the transparent part 19a. In the intermediate part between the lowermost layer part and the uppermost layer part in the resin body 18, the central part is the transparent part 19a and the circumference is the white part 19b, seen from the Z direction.

The transparent part 19a is in contact with the top face 11h of the lead frame 11 and the top face 12h of the lead frame 12. The die mount materials 13a and 13b, the LED chips 14a and 14b, the die mount material 15, the ZD chip 16, and the wire 17 are arranged inside the transparent part 19a. Accordingly, the transparent part 19a is in contact with the top face of the LED chip 14, and arranged at least between the top face of the LED chip 14 and a region immediately above the LED chip 14 on the top face of the resin body 18. In addition, the white part 19b is frame-shaped surrounding the transparent part 19a in the intermediate part of the resin body 18. The interface between the transparent part 19a and the white part 19b in the intermediate part of the resin body 18 is an inclined surface 19c which is inclined in a manner extending outward from the resin body 18 in the upward direction. The inclined surface 19c includes four planes and a curved surface connecting the planes.

In other words, the transparent part 19a has provided therein an inverted quadrangular pyramid trapezoid part with curved ridge lines provided in the intermediate part of the resin body 18, and a board-shaped part composing the uppermost layer part of the resin body 18, and the white part 19b has provided therein a figure-eight part surrounding the lead frames 11 and 12 and composing the lowermost layer part of the resin body 18, and a frame-shaped part provided on the circumferential part of the intermediate part of the resin body 18.

A number of fluorescent bodies 20 are distributed inside the transparent part 19a. Each phosphor 20 is granular, absorbs the light emitted from the LED chip 14 and emits light having a longer wavelength. For example, the fluorescent bodies 20 absorb a part of the blue light emitted from the LED chip 14 and emit yellow light. Accordingly, the LED chip 14 emits light from the LED package 1, where the blue light which has not been absorbed by the fluorescent bodies 20 and the yellow light which has been emitted from the fluorescent bodies 20 are emitted, so that the emitted light as a whole becomes white. For convenience of illustration, the fluorescent bodies 20 are drawn smaller in numbers and larger in size than in reality in FIGS. 2B and 2D. In addition, the fluorescent bodies 20 are omitted in the perspective and plan views.

As such a phosphor, a silicate phosphor which emits yellow-green, yellow, or orange light, for example, may be used. A silicate phosphor can be expressed by the following general formula.

{(2-x-y)SrO}{x(Baᵤ, Caᵥ)O}{(1-a-b-c-d)SiO₂}(aP₂O₅bA1₂O₃cB₂O₃dGeO₂):yEu2⁺

Here, 0<x, 0.005<y<0.5s, x+y≦1.6, 0≦a, b, c, d<0.5, 0<u, 0<v, u+v=1.

In addition, a YAG phosphor can also be used as the yellow phosphor. A YAG phosphor can be expressed by the following general formula.

(RE₁₋ₓSmₓ)₃(Al_{y}Ga_{1-y})₅O₁₂:Ce

Here, 0≦x<1s, 0≦y≦1, and RE is at least one type of element selected from Y and Gd.

Alternatively, a red phosphor and a green phosphor belonging to a sialon system can be mixed and used as the phosphor. In other words, the phosphor can be a green phosphor which absorbs blue light emitted from the LED chip 14 and emits green light, and a red phosphor which absorbs blue light and emits red light.

The sialon red phosphor can be expressed by the following general formula, for example.

(M₁₋ₓ, Rₓ)ₐ₁AlSi_{b1}O_{c1}N_{d1}

Here, M is at least one type of a metallic element other than Si and Al, and particularly preferred to be at least either Ca or Sr. R is a light emission central part element, and particularly preferred to be Eu. x, a1, b1, c1, and d1 satisfy 0<x≦1, 0.6<a1<0.95, 2<b1<3.9, 0.25<c1<0.45, and 4<d1<5.7.

A specific example of a sialon red phosphor is as follows.

Sr₂Si₇Al₇ON₁₃: Eu²⁺

A sialon green phosphor can be expressed by the following general formula, for example.

(M₁₋ₓ, Rₓ)ₐ₂AlSi_{b2}O_{c2}N_{d2}

Here, M is at least one type of a metallic element of other than Si and Al, and particularly preferred to be at least either Ca or Sr. R is a light emission central part element, and particularly preferred to be Eu. x, a2, b2, c2, and d2 satisfy 0<x≦1, 0.93<a2<1.3, 4.0<b2<5.8, 0.6<c2<1, and 6<d2<11.

A specific example of a sialon green phosphor is as follows.

Sr₃Si₁₃Al₃O₂N₂₁: Eu²⁺

Next a method of manufacturing an LED package according to the embodiment will be described.

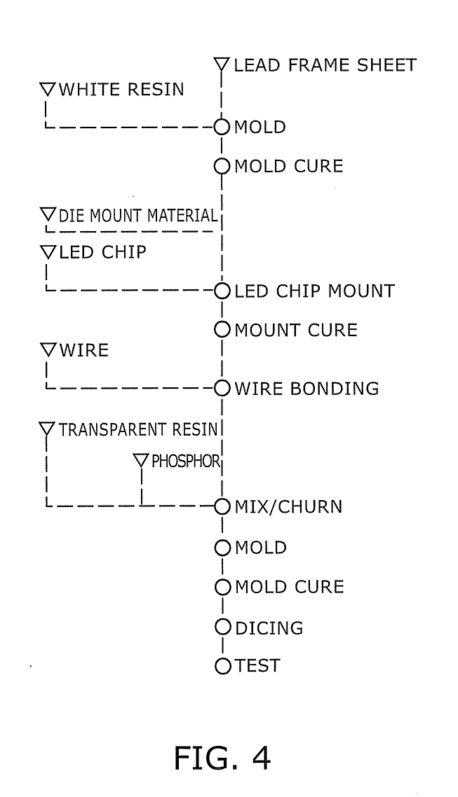

FIG. 4 is a flow chart showing a method of manufacturing an LED package according to the embodiment;

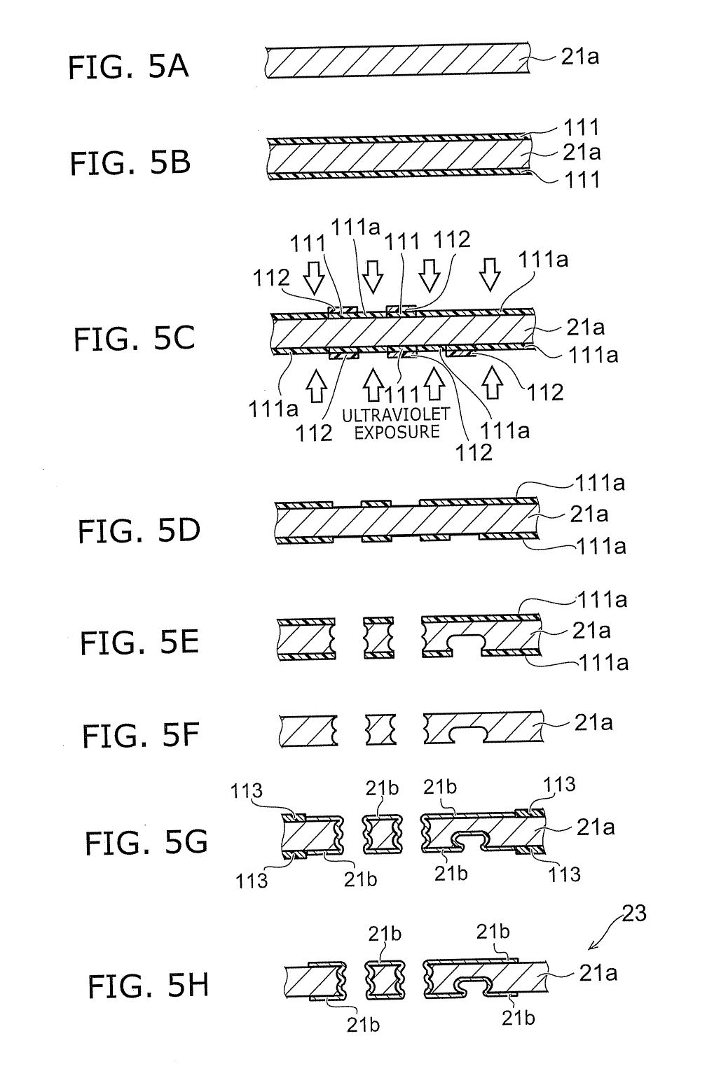

FIGS. 5A to 5H are process cross-sectional views showing a method of forming a lead frame sheet of the embodiment;

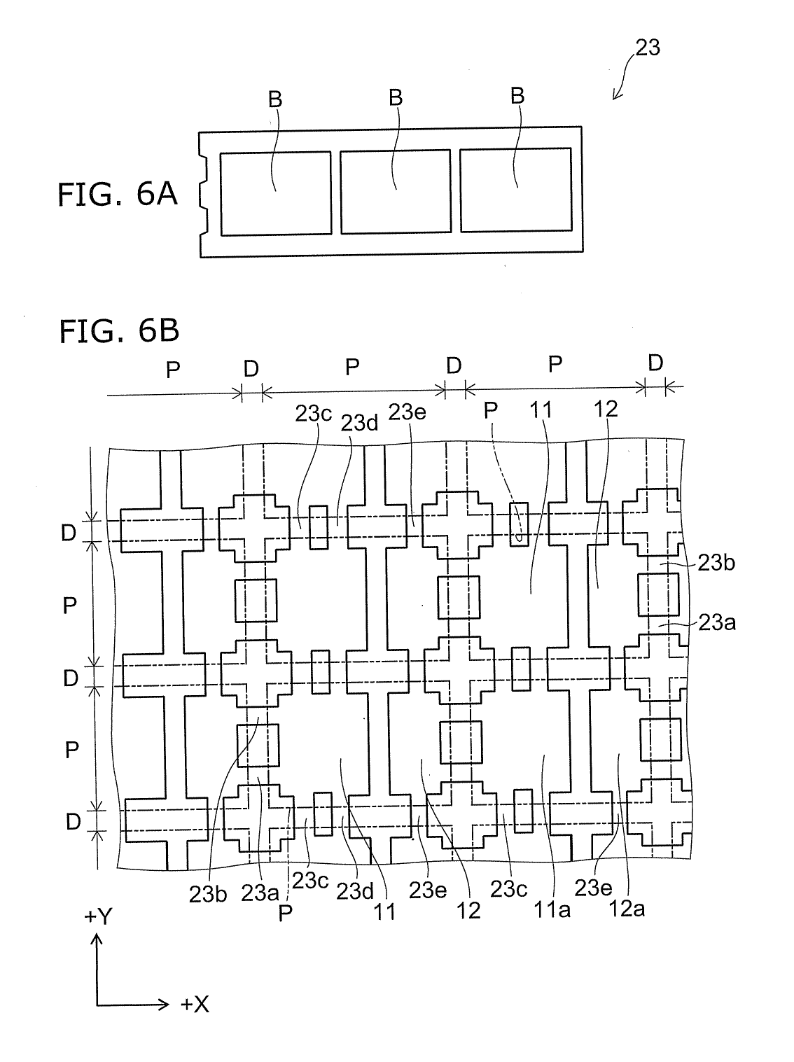

FIG. 6A is a plan view showing a lead frame sheet of the embodiment, whereas FIG. 6B is a partially enlarged plan view showing an element region of the lead frame sheet; and

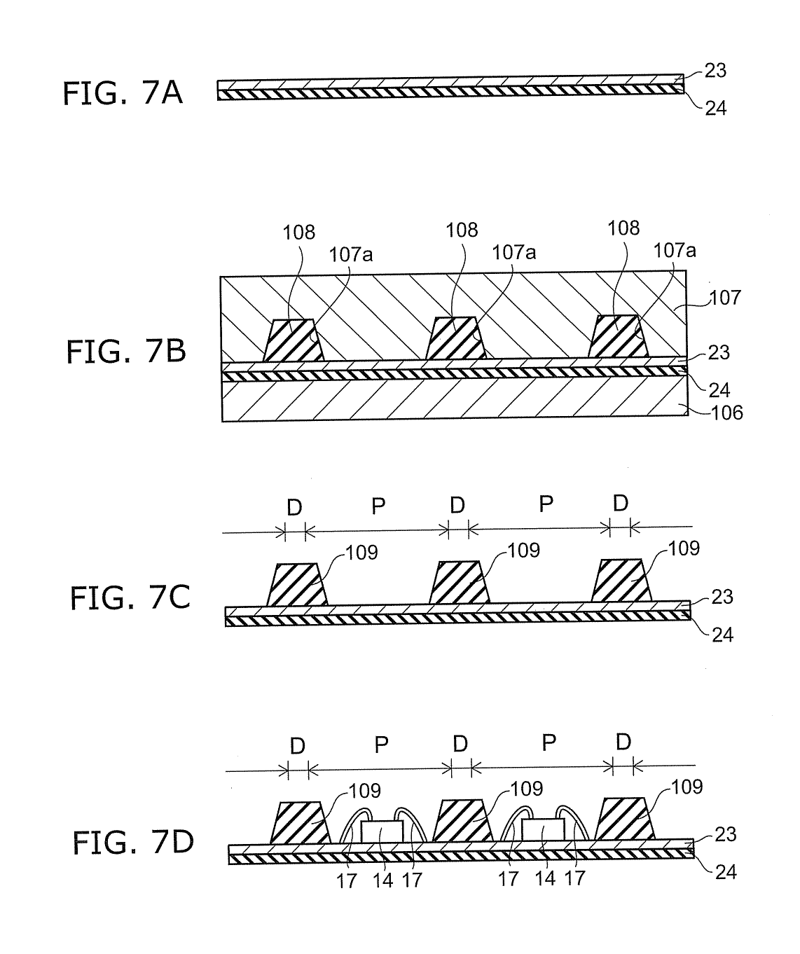

FIGS. 7A to 7D, FIGS. 8A to 8C, FIGS. 9A and 9B are process cross-sectional views showing a method of manufacturing an LED package according to the embodiment.

First, a lead frame sheet is formed, as shown in FIG. 4. In other words, a copper sheet 21a is prepared and washed, as shown in FIG. 5A. Next, resist coating is performed on both sides of the copper sheet 21a, which is dried thereafter to form a resist film 111, as shown in FIG. 5B. Next, a mask pattern 112 is arranged on the resist film 111 on which ultraviolet ray is irradiated for exposure, as shown in FIG. 5C. Accordingly, the exposed part of the resist film 111 cures to form a resist mask 111a. Next, the part which has not cured in the resist film 111 is developed and washed away, as shown in FIG. 5D. Accordingly, the resist pattern 111a remains on the top and bottom faces of the copper sheet 21a. Next, etching is performed, as shown in FIG. 5E, with the resist pattern 111a acting as a mask to remove the exposed part on the copper sheet 21a from both sides. In this occasion, the depth of etching is about as half as the thickness of the copper sheet 21a. Accordingly, the region which has been etched only from one side is half-etched, whereas the region which has been etched from both sides is penetrated. Next, the resist pattern 111a is removed, as shown in FIG. 5F. The end of the copper sheet 21a is then covered with a mask 113 for plating, as shown in FIG. 5G. Accordingly, a silver plating layer 21b is formed on a part of the surface other than the end of the copper sheet 21. Next, the mask 113 is washed away, as shown in FIG. 5H. Subsequently, an inspection is performed. As thus described, the lead frame sheet 23 has been manufactured

As shown in FIG. 6A, for example three blocks B are set in the lead frame sheet 23, each block B having for example about 1000 element regions P set therein. As shown in FIG. 5B, the element regions P are arranged in a matrix, and the interval between the element regions P is a lattice-shaped dicing region D. Each of the element regions P has a unit pattern formed therein including the lead frames 11 and 12 which are spaced apart from each other. In the dicing region D, the conductive material, which has formed the conductive sheet 21, remains in a manner connecting adjacent element regions P.

In other words, although the lead frames 11 and 12 are spaced apart from each other in the element regions P, a lead frame 11 belonging to a certain element region P is connected, via connecting parts 23a and 23b, to a lead frame 12 belonging to a next element region P located in the −X direction seen from the element region P. In addition, the lead frames 11 belonging to the element regions P adjacent to each other in the Y direction are connected via connecting parts 23c and 23d. Similarly, the lead frames 12 belonging to the element regions P adjacent to each other in the Y direction are connected via a connecting part 23e. As thus described, the connecting parts 23a to 23e respectively extend in three directions from the base portions 11a and 12a spaced apart from the outer edge of the element regions P in the lead frames 11 and 12 to pass the dicing region D and reach the next element regions P. Furthermore, the etching from the bottom face of the lead frame sheet 23 is performed as a half etching so that the protrusions 11p and 12p (see FIG. 2) are formed on the bottom face of the lead frames 11 and 12.

Next, a reinforcing tape 24 made of polyimide, for example, is adhered to the bottom face of the lead frame sheet 23, as shown in FIG. 7A. For convenience of illustration, the copper sheet 21a and silver plating layer 21b are collectively shown in the drawings including and after FIG. 7A as the lead frame sheet 23 without distinguishing therebetween.

Next, a lower die 106 and an upper die 107 are prepared, as shown in FIGS. 4 and 7B. The top face of the lower die 106 is flat. A depression 107a is formed on the bottom face of the upper die 107. The depression 107a is lattice-shaped, seen from the bottom face of the upper die 107. In addition, the side face of the depression 107a is inclined so that the closer to the bottom face of the upper die 107, the wider the width of the depression 107a becomes. Subsequently, the lead frame sheet 23 having the reinforcing tape 24 adhered thereto, and white resin 108a, for example, a tablet made of white silicone resin are inserted between the lower die 106 and the upper die 107 and molded. In this occasion, although the white resin 108 also goes around a part of the lead frame sheet 23 removed by half etching, it does not remain on the top face of the lead frame sheet 23 in the central part of the element regions P. Next, heat compression (mold cure) is applied on the white resin 108 using the lower die 106 and the upper die 107.

Next, the lower die 106 and the upper die 107 are removed from the lead frame sheet 23, as shown in FIG. 7C. Accordingly, a lattice-shaped white member 109 made of the white resin 108 is formed above the entire dicing region D and the circumference of the element region P on the lead frame sheet 23.

Next, the LED chips 14a and 14b, and the ZD chip 16 (see FIG. 1) are mounted on a region surrounded by the white member 109 on the top face of the lead frame sheet 23, i.e., the central part of each element regions P, and connected to the lead frames 11 and 12 with a wire 17, as shown in FIGS. 4 and 7D. For convenience of illustration, the LED chips 14a and 14b, and the ZD chip 16 are shown in FIGS. 7A to 9B as a single LED chip 14.

Specifically, the die mount materials 13a and 13b (see FIG. 1) are adhered on the top face of the lead frame 11 belonging to each of the element regions P of the lead frame sheet 23, and the die mount material 15 (see FIG. 1) is adhered on the top face of the lead frame 12. For example, a paste-like die mount material is discharged from a discharger on the lead frame, or transferred on the lead frame using a mechanical unit. Next, the LED chips 14a and 14b (see FIG. 1) are mounted on the die mount materials 13a and 13b. Also the ZD chip 16 (see FIG. 1) is mounted on the die mount material 15. Next, a heating process (mount-cure) is performed to sinter the die mount materials 13 and 15. Accordingly, the LED chips 14a and 14b are mounted on the lead frame 11 via the die mount materials 13a and 13b, and the ZD chip 16 is mounted on the lead frame 12 via the die mount material 15, in each of the element regions P of the lead frame sheet 23.

Next, one end of the wire 17 is bonded to the terminal 14s (see FIG. 1) of the LED chip 14 by supersonic wave bonding, for example, and the other end is bonded to a region located further in the −X direction than the groove 11m (see FIG. 1) on the top face of the lead frame 11. In addition, one end of another wire 17 is bonded to the terminal 14t of the LED chip 14 (see FIG. 1), and the other end is bonded to a region located further in the −Y direction than the groove 12m (see FIG. 1) on the top face of the lead frame 12. Accordingly, the LED chip 14 is connected between the lead frames 11 and 12 via the wire 17. On the other hand, one end of still another wire 17 is bonded to the top face terminal 16a of the ZD chip 16 (see FIG. 1), and the other end is bonded to a region located further in the +X direction than the groove 11n on the top face of the lead frame 11. Accordingly, the ZD chip 16 is connected between the lead frames 11 and 12 via the die mount material 15 and the wire 17.

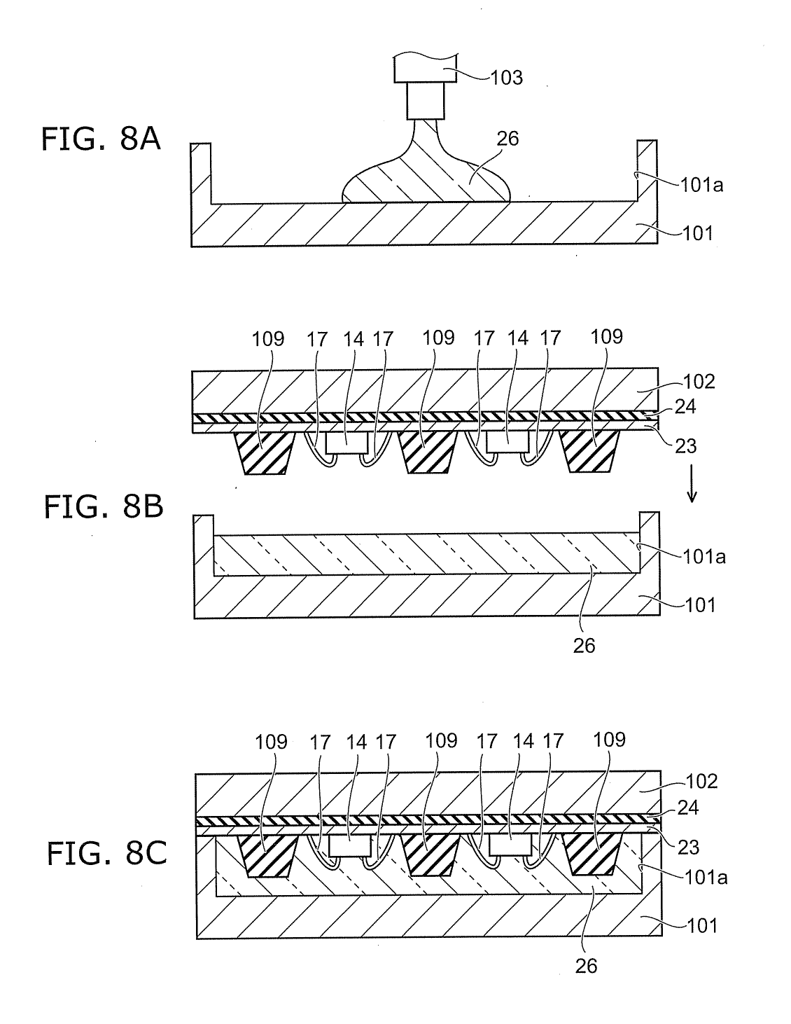

Next, a lower die 101 is prepared, as shown in FIGS. 4 and 8A. The lower die 101 composes a pair of dies together with an upper die 102 described below, and a depression 101a having a rectangular solid shape is formed on the top face of the lower die 101. A resin material 26 containing phosphors in a liquid or half-liquid state is prepared by mixing the phosphors 20 in a transparent resin such as transparent silicone resin and stirring thereof. When mixing the phosphors in the transparent silicone resin, the phosphors can also be uniformly dispersed in the resin using a thixotrope agent. The resin material 26 containing phosphors is supplied into the depression 101a of the lower die 101 using a dispenser 103.

Next, the lead frame sheet 23 having mounted thereon the LED chip 14 having the white member 109 formed thereon is attached to the bottom face of upper die 102 so that the white member 109 and the LED chip 14 turn downward, as shown in FIGS. 4 and 8B. Subsequently, the upper die 102 is pressed against the lower die 101 to clamp the mold. Accordingly, the lead frame sheet 23 is pressed against the resin material 26 containing phosphors. In this occasion, the resin material 26 containing phosphors covers the frame member 109, the LED chip 14, the wire 17 or the like. The resin material 26 containing phosphors is molded in this manner.

Heating-process (mold cure) is performed with the top face of the lead frame sheet 23 being pressed against the resin material 26 containing phosphors to cure the resin material 26 containing phosphors, as shown in FIGS. 4 and 8C.

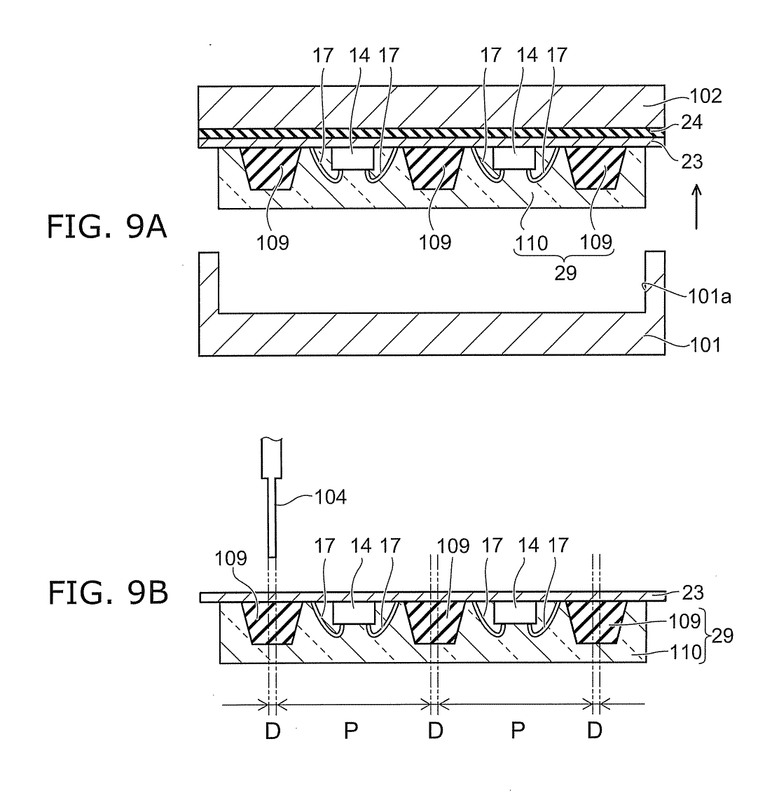

Next, the upper die 102 is separated from the lower die 101, as shown in FIG. 9A. Accordingly, a transparent member 110 is formed in a space surrounded by the white member 109, and on the bottom face of the white member 109. The part of the transparent member 110 surrounded by the white member 109 has a shape of an inverted quadrangular pyramid trapezoid, for example, and the part provided below the white member 109 is board-shaped. In addition, the LED chip 14 and the wire 17 are embedded in the transparent member 110. The resin plate 29 is formed by the white member 109 and the transparent member 110. The resin plate 29 covers the entire top face and a part of the bottom face of the lead frame sheet 23, and has the LED chip 14 is embedded therein. Subsequently, the reinforcing tape 24 is torn off from the lead frame sheet 23. Accordingly, the bottom faces of the protrusions 11p and 12p of the lead frames 11 and 12 (see FIG. 2) on the surface of resin plate 29 are exposed.

Next, dicing is performed on the integrated body including the lead frame sheet 23 and the resin plate 29 from the lead frame sheet 23 using a blade 104, as shown in FIGS. 4 and 9B. Accordingly, a part of the lead frame sheet 23 and the resin plate 29 which is provided in the dicing region D is removed. As a result, a part of the lead frame sheet 23 and the resin plate 29 which is provided in the element region P is divided into pieces, and thereby the LED package 1 shown in FIGS. 1 to 3 is manufactured. Dicing of the integrated body including the lead frame sheet 23 and the rising resin plate 29 may be performed from the resin body 29.

In each LED package 1 after dicing, the lead frames 11 and 12 are separated from the lead frame sheet 23. In addition, the resin plate 29 is divided to form the resin body 18. In this occasion, the white member 109 becomes the white part 19b and the transparent member 110 becomes the transparent part 19a. Dividing connecting parts 23a to 23d causes the extending portions 11b to 11g and 12b to 12e to be formed on the lead frames 11 and 12. The tip faces of the extending portions 11b to 11g and 12b to 12e are exposed on the side face of the resin body 18.

Next, various tests of the LED package 1 are performed, as shown in FIG. 4. In this occasion, the tip faces of the extending portions 11b to 11g and 12b to 12e can be used as testing terminals.

Next, the operating effect of the embodiment will be described.

The LED package 1 according to the embodiment has the transparent part 19a and the white part 19b provided in the resin body 18. The LED chip 14 is arranged in the transparent part 19a, with the white part 19b provided in a manner surrounding the transparent part 19a. Accordingly, most of the light emitted from the LED chip 14 and the light emitted from the phosphors is emitted upward (in the +Z direction). In other words, the LED package 1 has a high directivity of the emitted light. In addition, a part of the interface between the transparent part 19a and the white part 19b has been rendered into the inclined surface 19c extending outward from the resin body 18 in the upward direction, and thereby the light emitted horizontally from the LED chip 14 or the phosphors is reflected upward by the inclined surface 19c. This also improves the directivity of the emitted light.

In addition, the LED package 1 according to the embodiment has the white part 19b arranged on a part below the LED chip 14 of the resin body 18. Accordingly, the light emitted downward from the LED chip 14 is reflected at the interface between the transparent part 19a and the white part 19b and turns upward. Accordingly, the LED package 1 according to the embodiment has a high light extraction efficiency. In addition, the top faces of the lead frames 11 and 12 are exposed from the white part 19b . A silver plating layer is formed on the top faces and the bottom faces of the lead frames 11 and 12, and the light extraction efficiency can be further improved due to the high light reflectance of the silver plating layer.

Furthermore, the LED package 1 according to the embodiment has both the transparent part 19a and the white part 19b of the resin body 18 made of silicone resin. Since silicone resin has a high durability against light and heat, durability of the LED package 1 is improved. Therefore, the LED package 1 according to the embodiment has a long life and a high reliability, and can be applied to a wide range of usage. On the contrary, LED packages having an envelope made of polyamide thermoplastic resin absorb light and heat generated by the LED chip 14 and can be easily deteriorated.

Moreover, the LED package 1 according to the embodiment has the resin body 18 covering a part of the bottom faces and most of the end faces of the lead frames 11 and 12 so as to hold the periphery of the lead frames 11 and 12. In other words, a notch is created on the circumferential part of the bottom faces of the base portion 11a and 12a by forming the protrusions 11p and 12p on the central parts of the base portions 11a and 12a. The resin body 18 then turns around into the notch, and thereby the lead frames 11 and 12 can be firmly held. Accordingly, holdability of the lead frames 11 and 12 can be raised while exposing the bottom faces of the protrusions 11p and 12p of the lead frames 11 and 12 from the resin body 18 to realize an external electrode pad. Accordingly, it becomes difficult for the lead frames 11 and 12 to come off the resin body 18 during dicing, and thereby yield of the LED package 1 can be improved.

Moreover, the LED chips 14a and 14b are arranged diagonally to each other in the embodiment. Accordingly, the light emitted from one of the LED chips 14 is rarely incident on the other LED chip 14. This results in a high light extraction efficiency, and thereby heating of the LED chip 14 can be suppressed.

Furthermore, in the embodiment, the die mount materials 13a and 13b are adhered in a region located further in the +X direction and the wires 17a and 17c are bonded in a region located further in the −X direction, seen from the groove 11m on the top face 11h of the lead frame 11. In addition, the die mount material 13b is adhered in a region located further in the −X direction and the wire 17e is bonded in a region located further in the +X direction, seen from the groove 11n. Moreover, on the top face 12h of the lead frame 12, the die mount material 15 is adhered to a region located further in the +Y direction and the wires 17b and 17d are bonded in a region located further in the −Y direction, seen from the groove 12m. Accordingly, since the region where the die mount materials are adhered and the region where the wires are bonded on the top face of each lead frame are partitioned by a groove, it never happens that the die mount materials advance to the region where the wires are supposed to be bonded and disturb bonding of the wires. This results in a high reliability of the LED package 1 according to the embodiment.

Moreover, the ZD chip 16 is connected in parallel with the LED chips 14a and 14b in the embodiment. Therefore, the LED package 1 according to the embodiment has a high tolerance against ESD (Electrostatic Discharge).

Moreover, a large number, for example, about several thousands of the LED packages 1 can be collectively manufactured from a single conductive sheet 21 in the embodiment. In addition, dicing the lead frame sheet 23 and the resin plate 29 for each of the element regions P simply yields the LED packages 1. Accordingly, production cost per a single LED package can be reduced. In addition, the number of parts and processes for the LED package 1 can be reduced, which leads to cost reduction.

Moreover, the lead frame sheet 23 is formed by wet etching in the embodiment. Accordingly, it is only necessary to prepare the original mask when manufacturing an LED package of a new layout, and thereby the initial cost can be kept low compared with forming the lead frame sheet 23 by methods such as pressing with a die.

Moreover, extending portions extend from each of the base portions 11a and 12a of the lead frames 11 and 12 in the LED package 1 according to the embodiment. Accordingly, exposure of the base portion itself at the side face of the resin body 18 can be prevented, and thereby exposure area of the lead frames 11 and 12 can be reduced. As a result, detachment of the lead frames 11 and 12 from the resin body 18 can be prevented. In addition, erosion of the lead frames 11 and 12 can also be suppressed.

Reviewing the effect from the point of the manufacturing method, the number of metal parts intervening in the dicing region D is reduced by providing the connecting parts 23a to 23e in the lead frame sheet 23 in an intervening manner in the dicing region D, as shown in FIG. 6B. Accordingly, dicing becomes easy, and thereby abrasion of the dicing blade can be suppressed. Additionally, a plurality of extending portions extend from each of the lead frames 11 and 12 in three directions, in the embodiment. Accordingly, the lead frames 11 and 12 are securely supported from three directions by the lead frames 11 and 12 of the next element region P during the mounting process of the LED chip 14 and the ZD chip 16 shown in FIG. 7D, and thereby ease of mounting is realized. Similarly, in the wire bonding process, bonding position of the wire 17 is securely supported from three directions, and thereby, for example, supersonic waves applied when performing supersonic wave bonding rarely escape, and wires can be reliably bonded to the lead frames and LED chips.

Moreover, in the embodiment, dicing is performed from the lead frame sheet 23 in the dicing process shown in FIG. 9B. Accordingly, the metal material forming the cut end of the lead frame 11 and 12 extends over the side face of the resin body 18 in the +Z direction. Accordingly, it never happens that the metal material extends over the side face of the resin body 18 in the −Z direction to protrude from the bottom face of the LED package 1 and generate burr. Therefore, mounting failure due to burr never occurs when mounting the LED package 1.

Next, a second embodiment will be described.

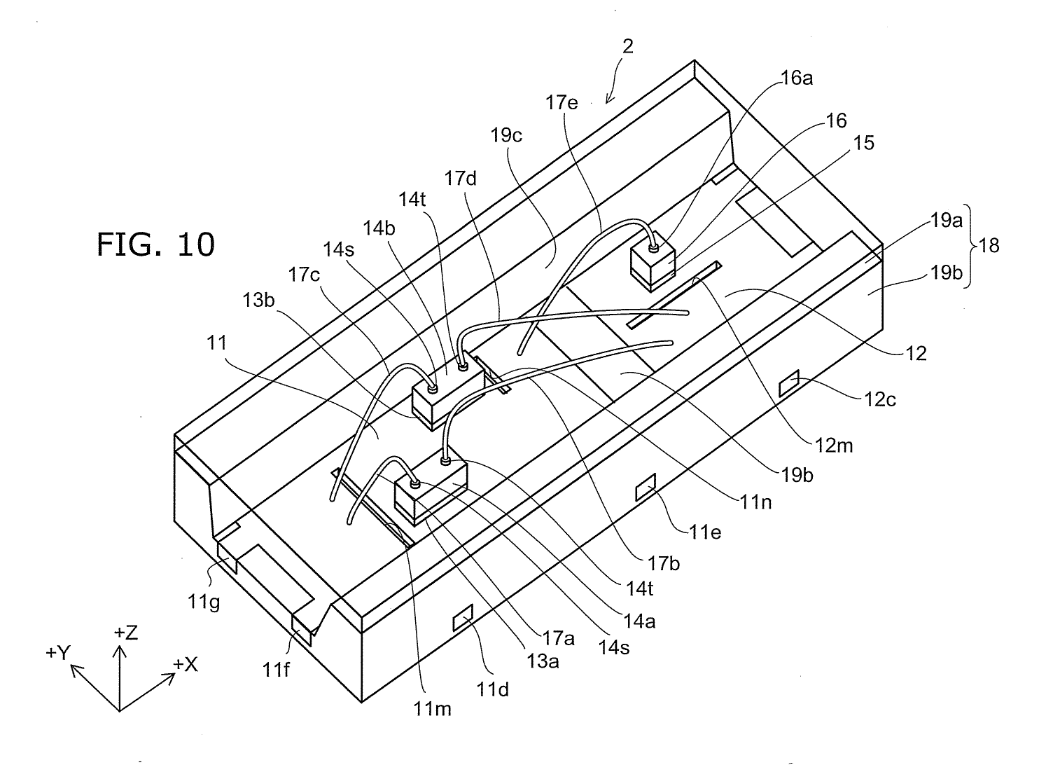

FIG. 10 is perspective view showing an LED package according to the embodiment; and

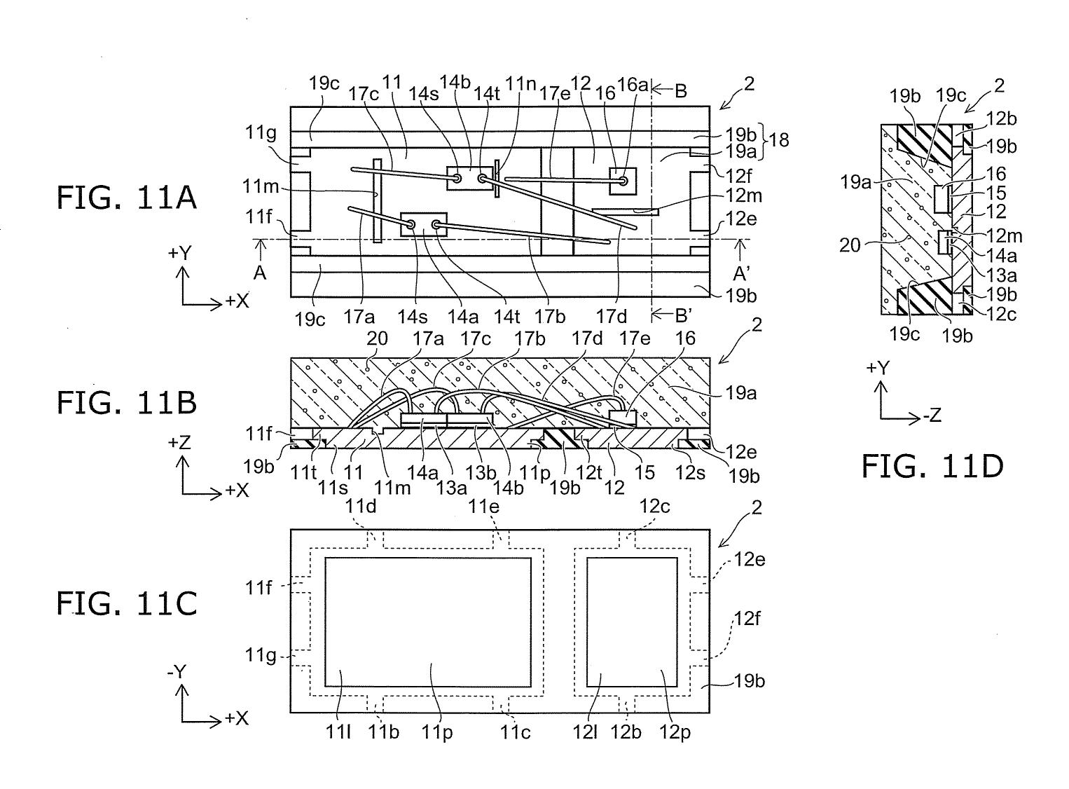

FIGS. 11A to 11D show the LED package according to the embodiment, in which FIG. 11A is a top view, FIG. 11B is a cross-sectional view taken along line A-A′ shown in FIG. 11A, t FIG. 11C is a bottom view, and FIG. 11D is a cross-sectional view taken along line B-B′ shown in FIG. 11A.

As shown in FIGS. 10 and 11, an LED package 2 according to the embodiment has a different shape of the transparent part 19a and the white part 19b of the resin body 18 from that of the LED package 1 according to the above-mentioned first embodiment (see FIGS. 1 to 3). In the embodiment, the white part 19b extends only in the long-side direction (X direction) of the resin body 18 and not in the short-side direction (Y direction) of the resin body 18, in the intermediate part excluding the uppermost layer part and the lowermost layer part of the resin body 18. In other words, the shape of the white part 19b in the intermediate part of the resin body 18 is not frame-shaped surrounding the LED chip 14 or the like but two-stripe-shaped extending in the X direction and sandwiching the LED chip 14 or the like in the Y direction. The transparent part 19a is provided across the entire length of the resin body 18 in the X direction, in the intermediate part of the resin body 18. The lowermost layer part of the resin body 18, i.e., the part below the top faces of the lead frames 11 and 12 includes the white part 19b. In addition, the uppermost layer part of the resin body 18 includes the transparent part 19a.

Such an LED package 2 can be manufactured in a molding process of the white resin 108 shown in FIG. 7B by forming the white member 109 in a stripe shape and not a lattice shape. The LED package 2 according to the embodiment has a high directivity of the emitted light in the Y direction, and can emit light in a wide angle range in the X direction. The configurations, manufacturing methods, and operational effects of the embodiment other than those described above are similar to the above-mentioned first embodiment.

Next, a third embodiment will be described.

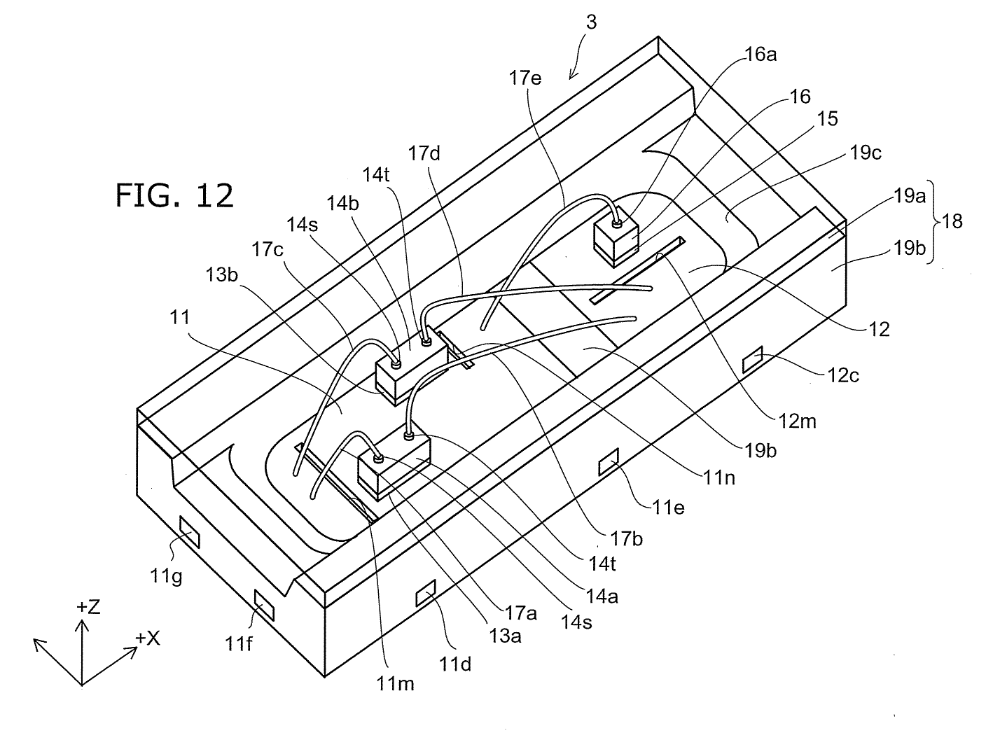

FIG. 12 is perspective view showing an LED package according to the embodiment; and

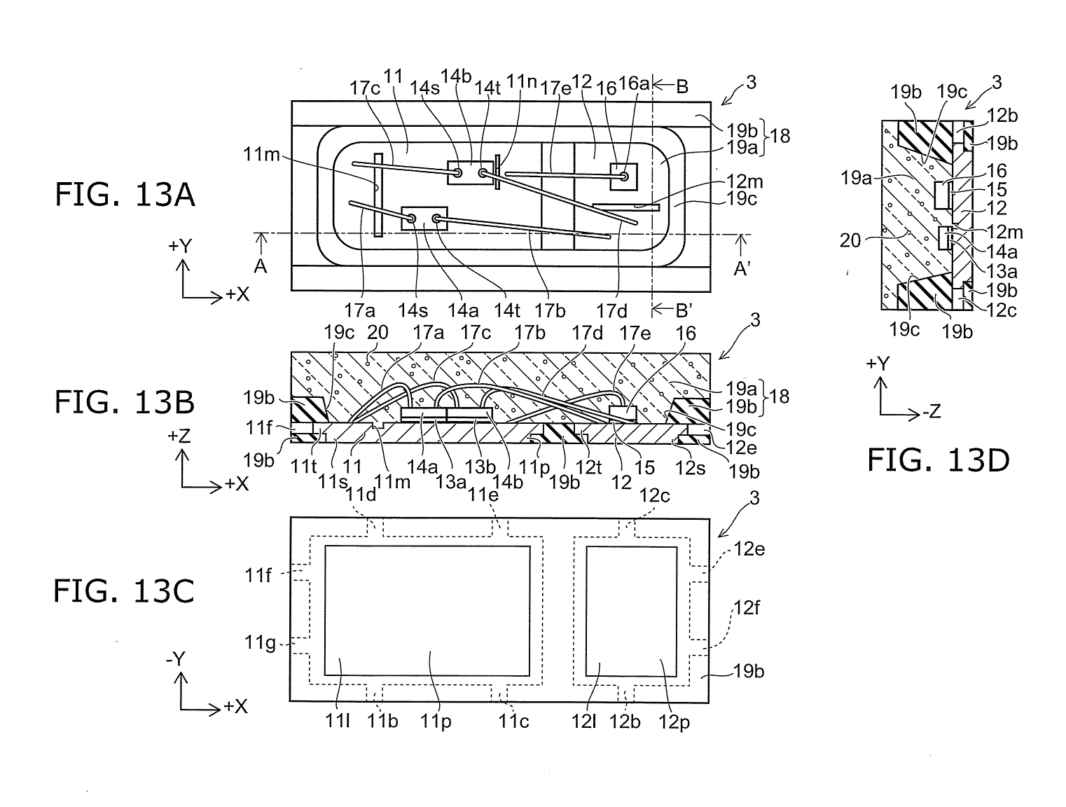

FIGS. 13A to 13D show the LED package according to the embodiment, in which FIG. 13A is a top view, FIG. 13B is a cross-sectional view taken along line A-A′ shown in FIG. 13A, FIG. 13C is a bottom view, and FIG. 13D is a cross-sectional view taken along line B-B′ shown in FIG. 13A.

As shown in FIGS. 12 and 13, an LED package 3 according to the embodiment is different from the LED package 1 according to the above-mentioned first embodiment (see FIGS. 1 to 3) in that the height of a part extending in the short-side direction (Y direction) of the resin body 18 is lower than the height of the part extending in long-side direction (X direction) of the resin body 18, in the white part 19b of the resin body 18. For example, the height of a part extending in the short-side direction (Y direction) of the resin body 18 in the white part 19b is about half the height of the part extending in the long-side direction (X direction), with the top faces of the lead frames 11 and 12 being the reference surface. The LED package 3 according to the embodiment has a high directivity of the emitted light in the Y direction, and can emit light in an angle range which is wide to some extent in the X direction. The configurations, manufacturing methods, and operational effects of the embodiment other than those described above are similar to the above-mentioned first embodiment.

Next, a fourth embodiment will be described.

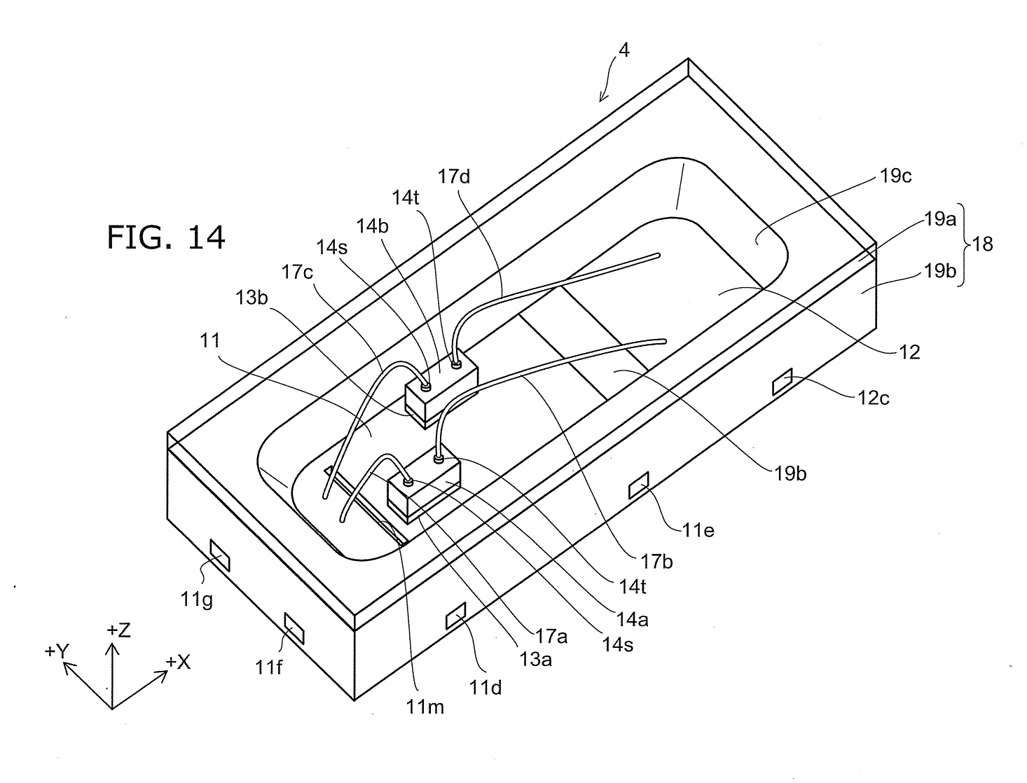

FIG. 14 is perspective view showing an LED package according to the embodiment; and

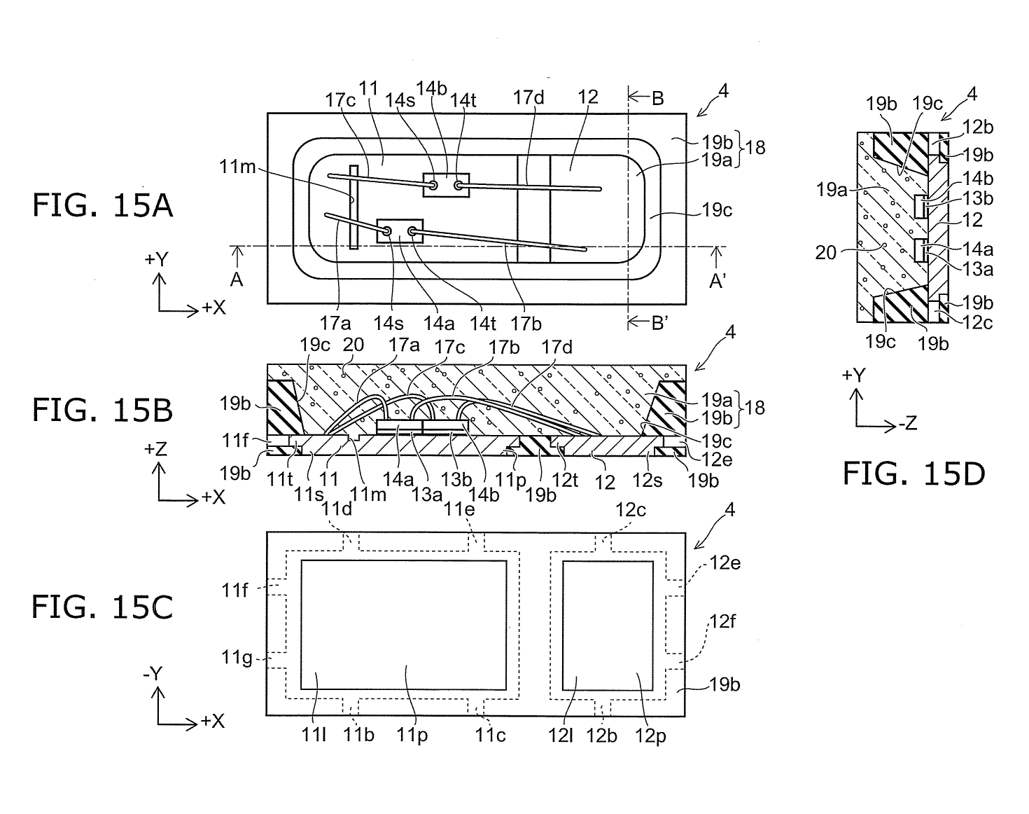

FIGS. 15A to 15D show the LED package according to the embodiment, in which FIG. 15A is a top view, FIG. 15B is a cross-sectional view taken along line A-A′ shown in FIG. 15A, FIG. 15C is a bottom view, and FIG. 15D is a cross-sectional view taken along line B-B′ shown in FIG. 15A.

As shown in FIGS. 14 and 15, an LED package 4 according to the embodiment is different from the LED package 1 according to the above-mentioned first embodiment (see FIGS. 1 to 3) in that the ZD chip 16 (see FIG. 1) is not provided therein. Since the ZD chip 16 is not provided, neither the die mount material 15 nor the wire 17e (see FIG. 1) is provided. In addition, neither the groove 11n for partitioning the bonding position of the wire 17e from the adhering region of the die mount materials 13b on the top face of the lead frame 11, nor the groove 12m for partitioning the bonding positions of the wires 17b and 17d from the adhering region of the die mount material 15 on the top face of the lead frame 12 is formed. Furthermore, the bonding position of the wire 17d is located further in the +X+Y direction than the above-mentioned first embodiment. The configurations, manufacturing methods, and operational effects of the embodiment other than those described above are similar to the above-mentioned first embodiment.

Next, a fifth embodiment will be described.

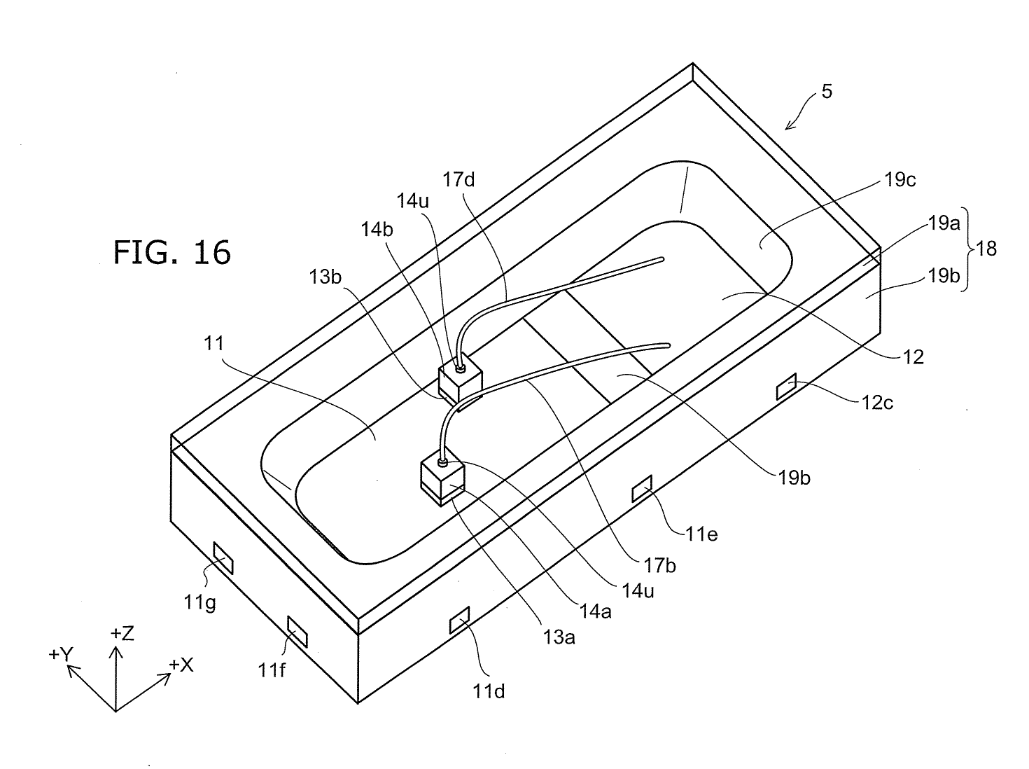

FIG. 16 is perspective view showing an LED package according to the embodiment; and

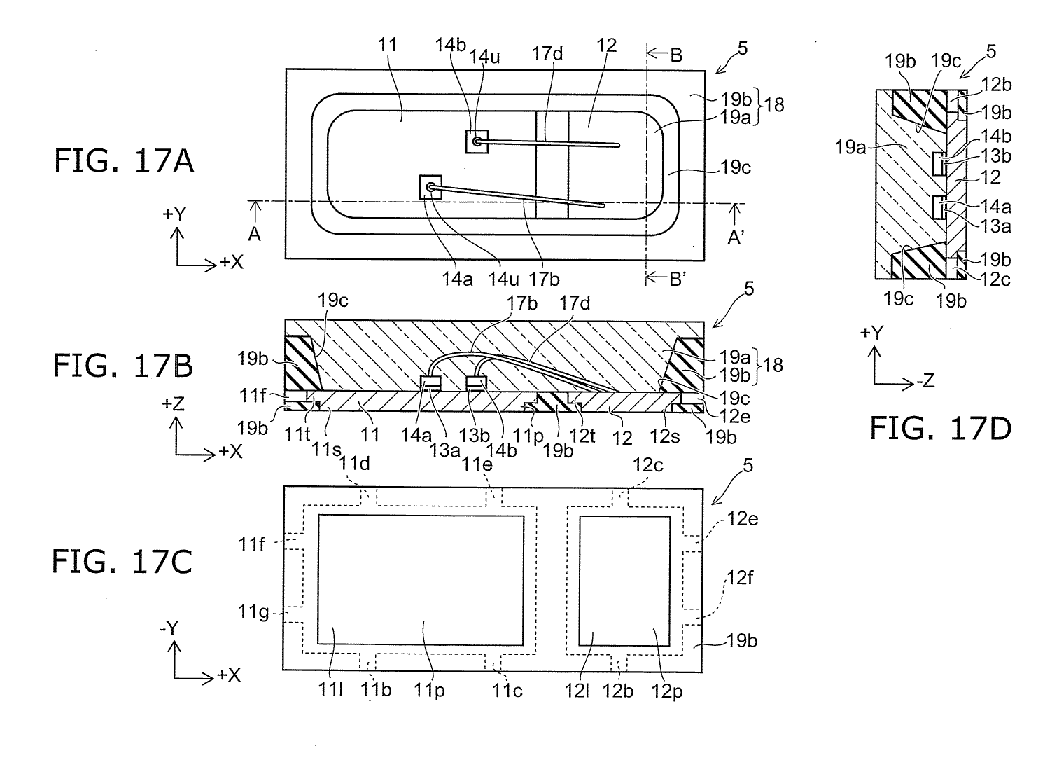

FIGS. 17A to 17D show the LED package according to the embodiment, in which FIG. 17A is a top view, FIG. 17B is a cross-sectional view taken along line A to A′ shown in FIG. 17A, FIG. 17C is a bottom view, and FIG. 17D is a cross-sectional view taken along line B-B′ shown in FIG. 17A.

As shown in FIGS. 16 and 17, an LED package 5 according to the embodiment is different from the LED package 4 according to the above-mentioned fourth embodiment (FIG. 14 and see FIG. 15) in that the LED chips 14a and 14b are vertically conductive chips which emit red light. The LED chips 14a and 14b have a top face terminal 14u and a bottom face terminal (not shown) provided thereon. Accordingly, neither the wire 17a nor 17c is provided. In addition, the groove 11m for partitioning the bonding positions the wires 17a and 17c from the adhering regions of the die mount materials 13a and 13b on the top face of the lead frame 11 is not formed. Furthermore, the phosphors 20 (see FIG. 15) are not dispersed in the transparent part 17a. The configurations, manufacturing methods, and operational effects of the embodiment other than those described above are similar to the above-mentioned first embodiment.

Next, a sixth embodiment will be described.

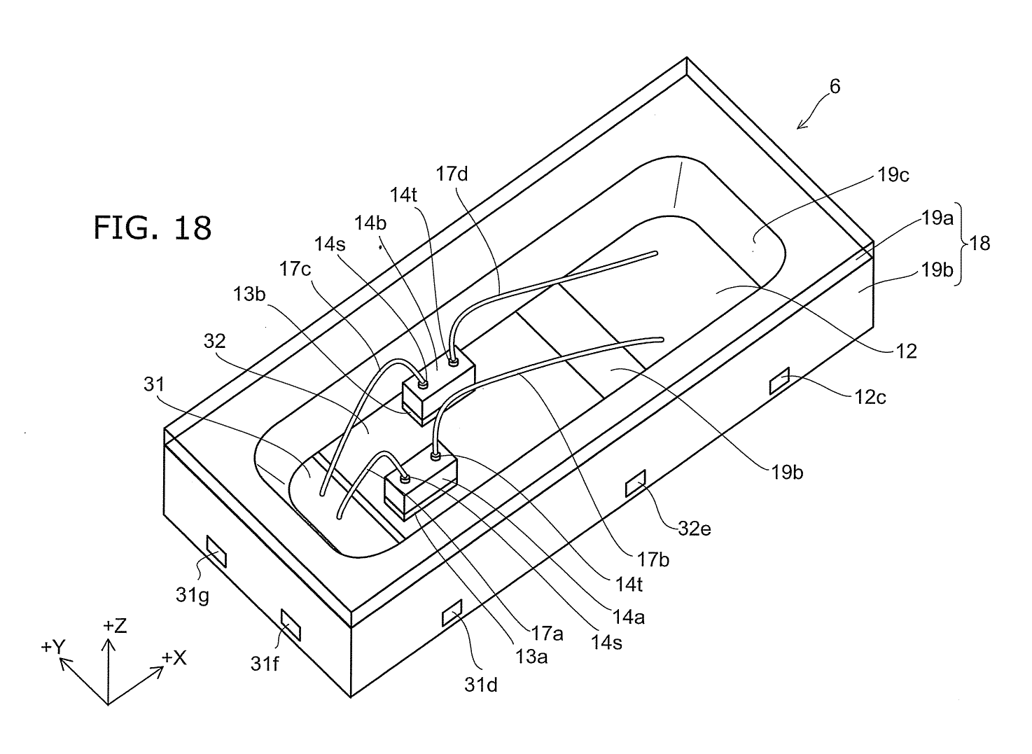

FIG. 18 is perspective view showing an LED package according to the embodiment;

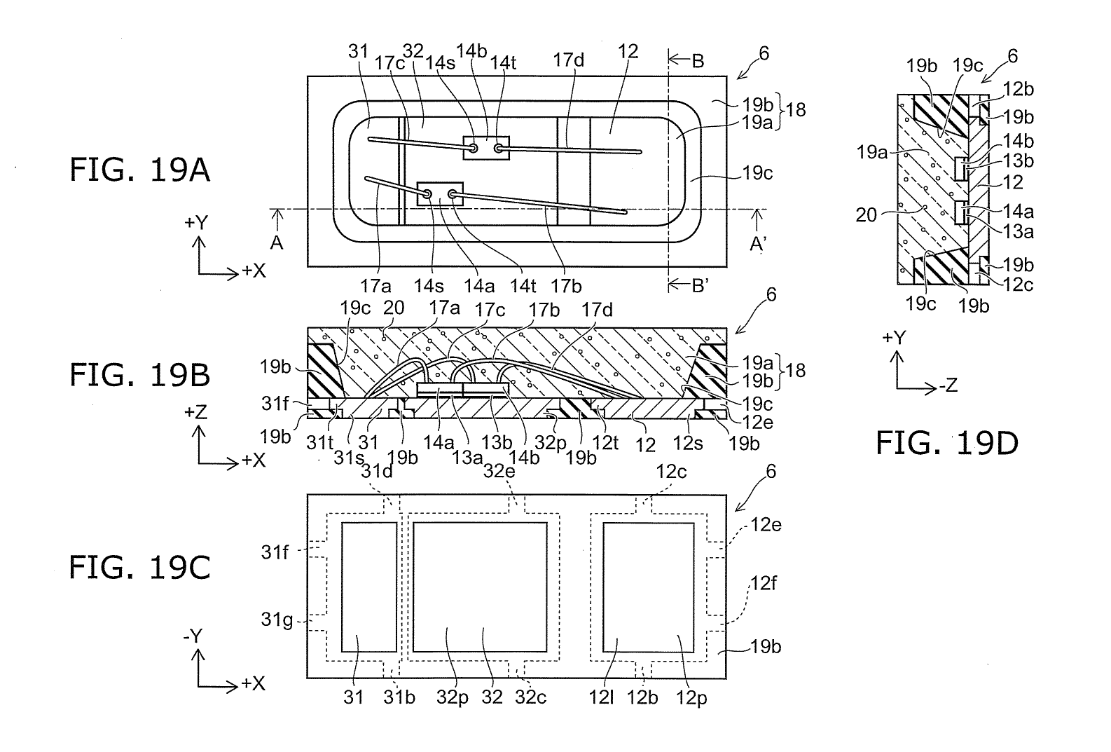

FIGS. 19A to 19D show the LED package according to the embodiment, in which FIG. 19A is a top view, FIG. 19B is a cross-sectional view taken along line A to A′ shown in FIG. 19A, FIG. 19C is a bottom view, and FIG. 19D is a cross-sectional view taken along line B-B′ shown in FIG. 19A; and

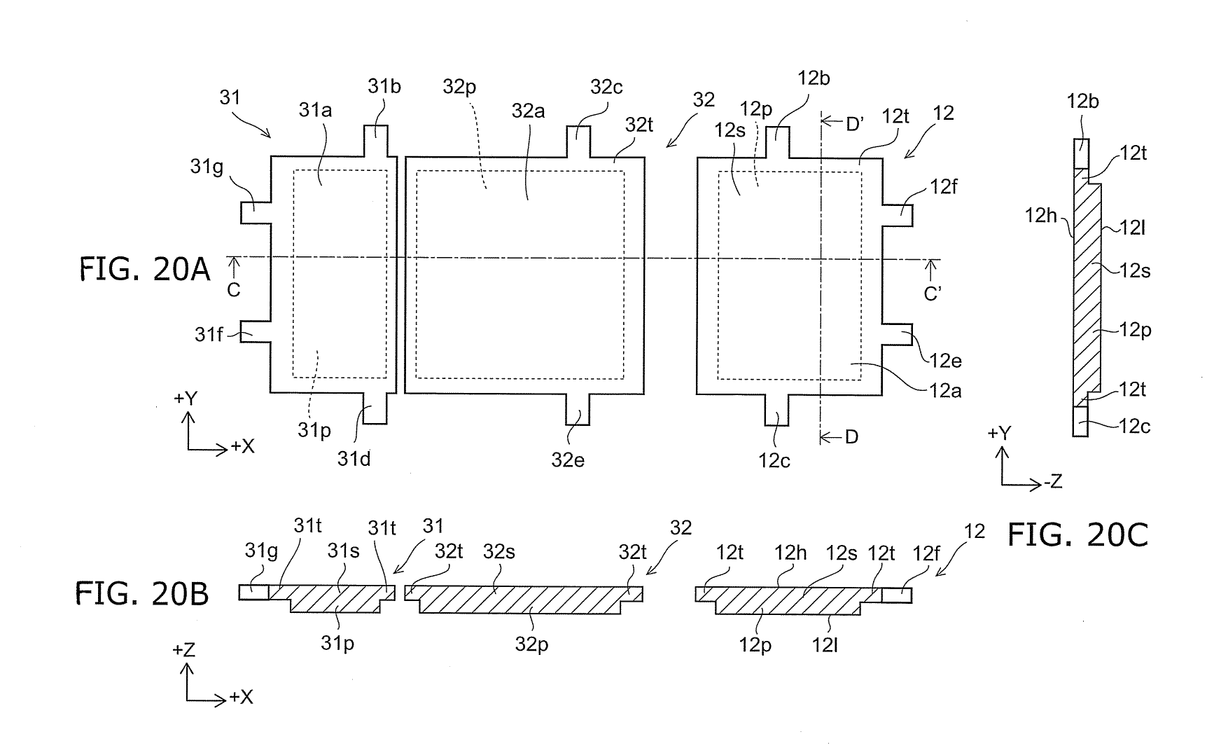

FIGS. 20A to 20C show lead frames of the LED package according to the embodiment, in which FIG. 20A is a top view, FIG. 20B is a cross-sectional view taken along line C-C′ shown in FIG. 20A, and FIG. 20C is a cross-sectional view taken along line D-D′ shown in FIG. 20A.

As shown in FIGS. 18 to 20, an LED package 6 according to the embodiment is different from the LED package 4 according to the above-mentioned fourth embodiment (see FIGS. 14 and 15) in that the lead frame 11 is divided into two lead frames 31 and 32 in the X direction. The lead frame 32 is provided between the lead frames 31 and 12.

The base portion 11a (see FIG. 15) of the lead frame 11 in the LED package 4 according to the above-mentioned fourth embodiment corresponds to the base portions 31a and 32b of the lead frames 31 and 32 in the embodiment. In addition, the extending portions 11b to 11g of the lead frame 11 correspond to the extending portions 31b, 32c, 31d, 32e, 31f, and 31g of the lead frames 31 and 32 in the embodiment. Furthermore, the protrusion 11p of the lead frame 11 is divided into the protrusion 31p of the lead frame 31 and the protrusion 32p of the lead frame 32. Seen from the Z direction, the protrusions 31p and 32p are respectively formed in the central parts of the base portions 31a and 32a. The wires 17a and 17c are bonded on the top face of the lead frame 31. As with the above-mentioned fourth embodiment, the wires 17b and 17d are bonded to the lead frame 12. In addition, since the ZD chip 16 (see FIG. 1) is not provided, neither the die mount material 15 nor the wire 17e is provided, and the grooves 11m, 11n, and 12m are not formed.

In the embodiment, the leads frame 31 and 12 have electric potential applied from outside to function as external electrodes. On the other hand, the lead frame 32 need not have electric potential applied thereto, and can be used as a lead frame dedicated for a heat sink. Accordingly, when mounting a plurality of LED packages 6 on a single module, the lead frame 32 can be connected to a common heat sink. The lead frame 32 may have a ground electric potential applied thereto, or may be in a floating state. Additionally, the so-called Manhattan phenomenon can be suppressed by bonding a solder ball to each of the lead frames 31, 32, and 12 when mounting the LED package 6 on a mother board. The Manhattan phenomenon refers to a phenomenon that, when mounting a device or the like on a substrate via a plurality of solder balls, causes the device to stand up due to a gap of the timing of fusion of the solder balls in a reflow furnace and surface tension of the solder, which may lead to mounting failure. According to the embodiment, the Manhattan phenomenon can be suppressed by densely providing the solder balls along the X direction.

In addition, the wires 17a and 17c can be easily bonded in the embodiment, because the lead frame 31 is supported from three directions by the extending portions 31b, 31d, 31f, and 31g. Similarly, the wire 17 can be easily bonded because the lead frame 12 is supported from three directions by the extending portions 12b to 12e.

Such an LED package 6 can be manufactured by a method similar to the above-mentioned first embodiment by changing the unit pattern of each of the element regions P of the lead frame sheet 23 in the process shown in the above-mentioned FIGS. 5A to 5H. In other words, LED packages with various types of layouts can be manufactured by changing the pattern of the mask pattern 112 according to the manufacturing method described in the above-mentioned first embodiment. The configurations, manufacturing methods, and operational effects of the embodiment other than those described above are similar to the above-mentioned fourth embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

In the above-mentioned first embodiment, for example, although an example has been shown in which the lead frame sheet 23 is formed by wet etching, the invention is not limited thereto and it may be formed by a mechanical method such as pressing, for example. Additionally, in the above-mentioned first embodiment, although an example has been shown in which the lead frame has silver plating layers formed on the top and bottom faces of a copper sheet, the invention is not limited thereto. For example, with the silver plating layers having been formed on the top and bottom faces of the copper sheet, a rhodium (Rh) plating layer may be formed on at least one of the silver plating layers. In addition, a copper (Cu) plating layer may be formed between the copper sheet and the silver plating layers. Furthermore, with nickel (Ni) plating layers having been formed on the top and bottom face of the copper sheet, a gold and silver alloy (Au—Ag alloy) plating layer may be formed on the nickel plating layer.

Additionally, in the above-mentioned first embodiment, although an example has been shown in which the LED chip emits blue light, the phosphors absorbs the blue light and emits yellow light, and the color of light to be emitted from the LED package is supposed to be white, the invention is not limited thereto. The LED chip may emit visible light other than blue, or may emit ultraviolet or infrared rays. The phosphors also is not limited emitting yellow light, but it maybe one that emits blue, green, or red light.

In addition, the color of light emitted by the entire LED package is not limited to white. Any color tone can be realized for the red, green, and blue fluorescent bodies described above by adjusting their weight ratio R:G:B. For example, white light emission ranging from white electric bulb color to white fluorescent lamp color can be realized by setting the R:G:B weight ratio to any of 1:1:1 to 7:1:1, 1:1:1 to 1:3:1, and 1:1:1 to 1:1:3.

Furthermore, the LED package need not have a phosphors provided therein. In this case, the light emitted from the LED chip is emitted from the LED package.

According to the embodiments described above, a low cost LED package and a method for manufacturing the same can be realized.

What is claimed is:

1. An LED package comprising:
a first lead frame and a second lead frame spaced apart from each other;
an LED chip provided above the first lead frame and the second lead frame and having one terminal connected to the first lead frame and the other terminal connected to the second lead frame, and
a resin body covering the LED chip, covering the top face, a part of the bottom face and a part of the end face, of each of the first and the second lead frames, and exposing the remaining part of the bottom face and the remaining part of the end face,
the resin body including:
a first part disposed between the top face of the LED chip and a region immediately above the LED chip of the top face of the resin body to transmit light emitted by the LED chip; and
a second part surrounding the first part and having a transmittance of the light lower than a transmittance in the first part,
an external shape of the resin body defining an external shape of the LED package.

2. The package according to claim 1, wherein
a reflectance of the light on the external surface of the second part is higher than a reflectance on the external surface of the first part.

3. The package according to claim 1, wherein
the first part is transparent and the second part is white.

4. The package according to claim 1, wherein
the first part and the second part are formed of silicone resin.

5. The package according to claim 1, wherein
the bottom face of the resin body is formed of the second part.

6. The package according to claim 1, wherein
the top face of the resin body is formed of the first part.

7. The package according to claim 1, wherein
a part of an interface between the first part and the second part is inclined so as to extend outward from the resin body toward upward.

8. The package according to claim 1, further comprising phosphors disposed in the first part.

9. The package according to claim 1, wherein
one of the first lead frame and the second lead frame includes:
a base portion having an end face thereof covered by the resin body; and
three extending portions extending from the base portion in directions different from each other, having bottom faces thereof covered by the resin body, and having tip faces thereof exposed on a side face of the resin body,
a protrusion is formed in a region of one of the bottom face of the first lead frame and the bottom face of the second lead frame, the region is spaced apart from the other, the bottom face of the protrusion is exposed on the bottom face of the resin body, and the side face of the protrusion is covered by the resin body.

10. The package according to claim 1, wherein
the second part contains a reflective material including titanium oxide.

11. The package according to claim 1, wherein
the reflectance on the external surface of the second part is not less than 80% of the light region where the wavelength is in a range of 800 to 350 nm.

12. The package according to claim 11, wherein
the reflectance on the external surface of the second part is not less than 90% of the light region where the wavelength is in a range of 800 to 350 nm.
